(19) United States
(12) Patent Application Publication
(10) Pub. No.: US 2025/0048791 A1
(43) Pub. Date: Feb. 6, 2025

(54) LIGHT EMITTING DIODE AND LIGHT EMITTING DEVICE

(71) Applicant: Tianjin Sanan Optoelectronics Co., Ltd., Tianjin (CN)

(72) Inventors: Jingjuan LU, Tianjin (CN); Shoushuai GAO, Tianjin (CN); Xiaoxi LI, Tianjin (CN); Dongyan ZHANG, Tianjin (CN)

(73) Assignee: Tianjin Sanan Optoelectronics Co., Ltd., Tianjin (CN)

(21) Appl. No.: 18/761,173

(22) Filed: Jul. 1, 2024

(30) Foreign Application Priority Data
Aug. 1, 2023 (CN) 202310960178.X

(51) Int. Cl. H01L 33/20; H01L 33/00; H01L 33/62

(52) U.S. Cl. CPC H01L 33/20; H01L 33/0062; H01L 33/62

(57) ABSTRACT

Disclosed is a light emitting diode including a semiconductor stack, a first electrode, and a second electrode. The semiconductor stack including a first semiconductor layer, a light emitting layer, and a second semiconductor layer has a terrace. The first electrode located on a terrace of the semiconductor stack is electrically connected to the first semiconductor layer. The second electrode is electrically connected to the second semiconductor layer. Two ends of a first inclined sidewall of the semiconductor stack are respectively connected to an upper surface of the second semiconductor layer and the terrace. An included angle between the first inclined sidewall and the terrace ranges from 110° to 135°. An interval between the first electrode and the light emitting layer ranges from 2.5 μm to 13 μm. By the configuration, the reliability and the ESD protection performance of the LED can be improved.

### CROSS-REFERENCE TO RELATED APPLICATION

This application claims the priority benefit of China application serial no. 202310960178.X, filed on Aug. 1, 2023. The entirety of the above-mentioned patent application is hereby incorporated by reference herein and made a part of this specification.

### BACKGROUND

### Technical Field

The disclosure relates to a field of semiconductor manufacturing technology, and in particular to a light emitting diode and a light emitting device.

### Description of Related Art

A light emitting diode (LED) is a light-emitting semiconductor element, usually made of semiconductor such as GaN, GaAs, GaP, GaAsP, etc., and a main portion of the LED is a p-n junction having light emitting properties. The LED has the advantages of high intensity of light, high efficiency, small size, and long lifetime, and is currently considered to be one of the most promising light sources. The LED has been widely used in lighting, monitoring and command, high-definition broadcasting, high-quality cinemas, office displays, conference interaction, virtual reality, and other fields.

Currently, conventional flipped red LEDs generally have the issues of low reliability and poor ESD (electrical static discharge) protection performance. Therefore, how to solve the conditions of red LEDs has become one of the most important issues for people skilled in the art.

It should be noted that the information disclosed in this background technology section is only intended to increase the understanding of the overall background of the disclosure, and should not be regarded as acknowledging or suggesting in any form that the information constitutes related art already known to people skilled in the art.

### SUMMARY

The disclosure provides a light emitting diode which includes a semiconductor stack, a first electrode, and a second electrode.

The semiconductor stack includes a first semiconductor layer, a light emitting layer, and a second semiconductor layer stacked in sequence. The semiconductor stack has a terrace, which is an upper surface of the first semiconductor layer not covered by the light emitting layer. The first electrode is located on the terrace and is electrically connected to the first semiconductor layer. The second electrode is electrically connected to the second semiconductor layer. The semiconductor stack has a first inclined sidewall, and two ends of the first inclined sidewall are respectively connected to an upper surface of the second semiconductor layer and the terrace. An included angle between the first inclined sidewall and the terrace is in a range of 110° to 135°. An interval between the first electrode and the light emitting layer is in a range of 2.5 μm to 13 μm.

The disclosure further provides a light emitting device, which adopts the light emitting diode.

An embodiment of the disclosure provides a light emitting diode and a light emitting device. By controlling the included angle between the first inclined sidewall and the terrace to be within the range of 110° to 135° and controlling the interval between the first electrode and the light emitting layer to be within the range of 2.5 μm to 13 μm, the reliability and the ESD protection performance of the LED can be improved.

Other features and beneficial effects of the disclosure will be described in the following description, and some of the technical features and beneficial effects can be obviously derived from the description or understood by implementing the disclosure.

### BRIEF DESCRIPTION OF THE DRAWINGS

In order to more clearly illustrate the embodiments of the disclosure or the technical solutions in the related art, a brief introduction is given below to the drawings required for use in the embodiments or the description of the related art. Obviously, some of the drawings described below are some embodiments of the disclosure. For people skilled in the art, other drawings can be obtained based on these drawings without paying creative work.

FIG. 1 is a schematic view of a structure of a light emitting diode according to an embodiment of the disclosure.

FIG. 2 is a schematic top view of a structure of a light emitting diode according to an embodiment of the disclosure.

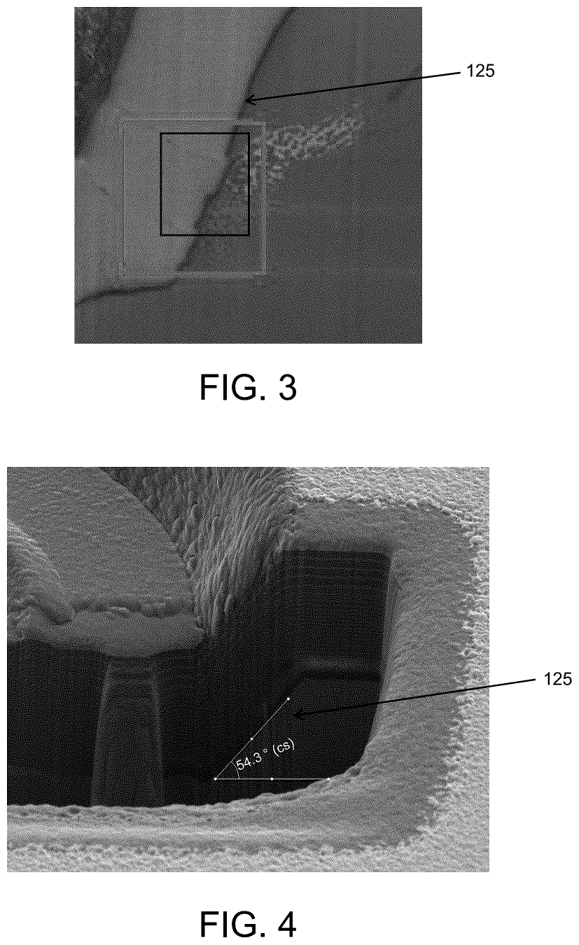

FIG. 3 is a scanning electron microscope (SEM) image of a semiconductor stack of a conventional LED;

FIG. 4 is a SEM image of a semiconductor stack of a LED according to an embodiment of the disclosure.

FIG. 5 to FIG. 9 are schematic views of the structure of the LED shown in FIG. 1 at various stages in a manufacturing process.

### DESCRIPTION OF THE EMBODIMENTS

In order to make the purpose, technical solution, and advantages of the embodiments of the disclosure clearer, the technical solution in the embodiments of the disclosure will be clearly and completely described below in conjunction with the drawings in the embodiments of the disclosure. Obviously, the described embodiments are only part of the embodiments of the disclosure, but not all of the embodiments. The technical features designed in the different embodiments of the disclosure described below can be combined with each other as long as they do not conflict with each other. Based on the embodiments of the disclosure, all other embodiments obtained by people skilled in the art without making any creative work shall fall within the scope of protection of the disclosure.

In the description of the disclosure, it should be understood that the terms “center”, “lateral”, “up”, “down”, “left”, “right”, “vertical”, “horizontal”, “top”, “bottom”, “inside”, “outside”, etc., indicating the orientation or position relationship are based on the orientation or position relationship shown in the drawings, and are only for the convenience of describing the disclosure and simplifying the description, rather than indicating or implying that the device or component referred to must have a specific orientation, or be constructed and operated in a specific orientation, and therefore cannot be understood as a limitation on the disclosure. In addition, the terms “first” and “second” are used for descriptive purposes only and should not be understood as indicating or implying relative importance or implicitly indicating the quantity of the indicated technical features. Therefore, features defined as “first” or “second” may explicitly or implicitly include one or more of such features. In the description of the disclosure, unless otherwise specified, “plurality” means two or more. In addition, the term “include” and any variations thereof all mean “include at least”.

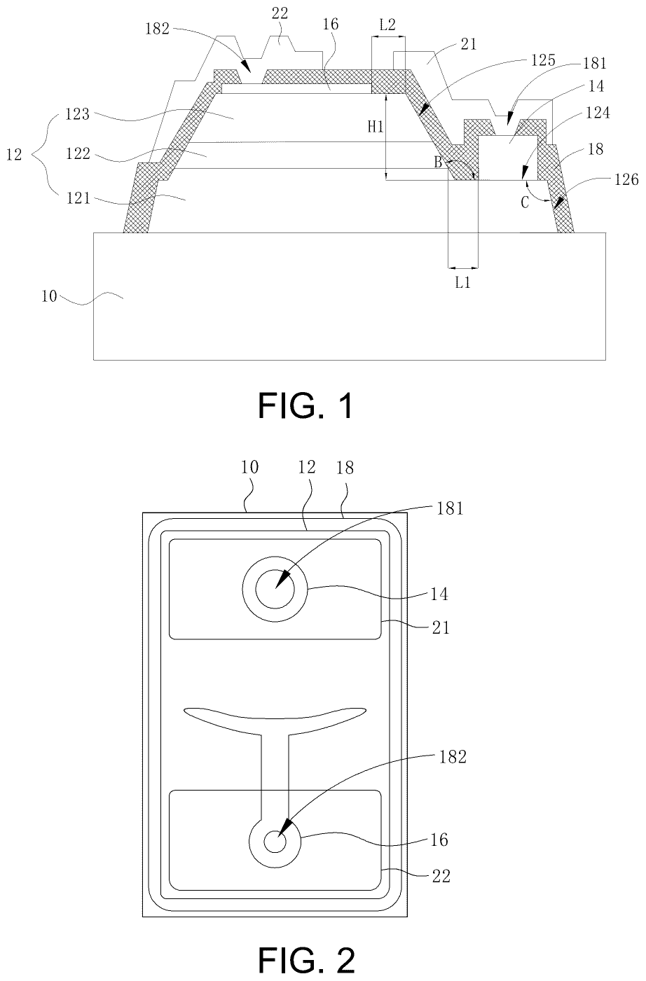

Please refer to FIG. 1, which is a schematic view of a structure of a light emitting diode according to an embodiment of the disclosure. To achieve at least one of the above advantages or other advantages, an embodiment of the disclosure provides a light emitting diode. As shown in the figure, the LED includes a semiconductor stack 12, a first electrode 14, and a second electrode 16.

The semiconductor stack 12 includes a first semiconductor layer 121, a light emitting layer 122, and a second semiconductor layer 123 stacked in sequence. The semiconductor stack 12 has a terrace 124, which refers to an upper surface of the first semiconductor layer 121 that is not covered by the light emitting layer 122. The terrace 124 is used to set an electrode thereon, and the electrode forms a good ohmic contact with the first semiconductor layer 121.

The first semiconductor layer 121 may be a P-type semiconductor layer, providing holes to the light emitting layer 122 under a power source. The first semiconductor layer 121 may be implemented as a material layer providing holes by p-type doping. The P-type semiconductor layer may be doped with a p-type dopant such as Mg, Zn, Ca, Sr, or Ba. The second semiconductor layer 123 may be a single-layer structure or a multi-layer structure. The multi-layer structure has different compositions.

The light emitting layer 122 may be a quantum well (QW) structure. In some embodiments, the light emitting layer 122 may also be a multiple quantum well (MQW) structure. The MQW structure includes multiple quantum well layers and multiple quantum barrier layers alternately arranged in a repeated manner, which may, for example, be GaN/AlGaN, InAlGaN/InAlGaN, InGaN/AlGaN, and AlGaInP/AlGaInP. In addition, the composition and thickness of the quantum well layer in the light emitting layer 122 determine a wavelength of the generated light. In order to improve the light emitting efficiency of the light-emitting layer 122, the depth of the QW, the number of layers with paired quantum well layer and quantum barrier layer, the thickness, and/or other characteristics of the light emitting layer 122 may be changed.

The second semiconductor layer 123 may be an N-type semiconductor layer, providing electrons to the light emitting layer 122 under the power source. The second semiconductor layer 123 may be implemented as a material layer providing electrons by n-type doping. The N-type semiconductor layer may be doped with an n-type dopant such as Si, Ge, or Sn.

The first semiconductor layer 121, the light emitting layer 122, and the second semiconductor layer 123 may be made of materials such as aluminum gallium indium nitride, gallium nitride, aluminum gallium nitride, aluminum indium phosphide, aluminum gallium indium phosphide, gallium arsenide, or aluminum gallium arsenide. The first semiconductor layer 121 or the second semiconductor layer 123 may include a cover layer providing electrons or holes and include other layer materials, such as a current spreading layer, a window layer, or an ohmic contact layer. Different multiple layers are formed according to different doping concentrations or different component contents. The light emitting layer 122 is a region where electrons and holes recombine to generate light radiation, and different materials may be selected according to different light emission wavelengths. The light emitting layer 122 may be a single QW or a MQW having periodic structure. By adjusting the composition ratio of the semiconductor materials in the light emitting layer 122, it is desired to radiate light of different wavelengths. In this embodiment, the material of the light emitting layer 122 is preferably aluminum gallium indium phosphide or aluminum gallium arsenic. The light emitting layer 122 may radiate red light or infrared light. The LED may be a red LED. The LED may be a flipped structure.

The semiconductor stack 12 has a first inclined sidewall 125. The upper and lower ends of the first inclined sidewall 125 are respectively connected to an upper surface of the second semiconductor layer 123 and the terrace 124. By controlling an included angle B between the first inclined sidewall 125 and the terrace 124 to be in a range of 110° to 135° and controlling an interval L1 between the first electrode 14 and the light emitting layer 122 to be in a range of 2.5 μm to 13 μm, the reliability and the electrical static discharge (ESD) protection performance of the LED can be improved. If the included angle is greater than 135°, the first inclined sidewall 125 would be inclined toward the light emitting layer 122, which results in a smaller area of the light emitting layer 122 and a reduced amount of light. An area of the terrace 124 on which the light emitting layer 122 is not disposed also becomes smaller, causing the subsequently disposed first electrode 14 to be closer to the light emitting layer 122 (for example, the interval L1 between the first electrode 14 and the light emitting layer 122 would be less than 2.5 μm), reducing the ESD protection performance and increasing the short circuit risks. If the included angle is less than 110°, the first inclined sidewall 125 would be more vertical and steeper. When an insulating layer 18 and a first pad 21 subsequently cover the terrace 124 and the first inclined sidewall 125, cracks and grooves would be easily formed, which affects the reliability of the LED. Furthermore, the area of the terrace 124 on which the light emitting layer 122 is not disposed also becomes larger, causing the subsequently disposed first electrode 14 to be further away from the light emitting layer 122 (for example, the interval L1 between the first electrode 14 and the light emitting layer 122 would be greater than 13 μm), resulting in poor current conduction and affecting the performance of the LED.

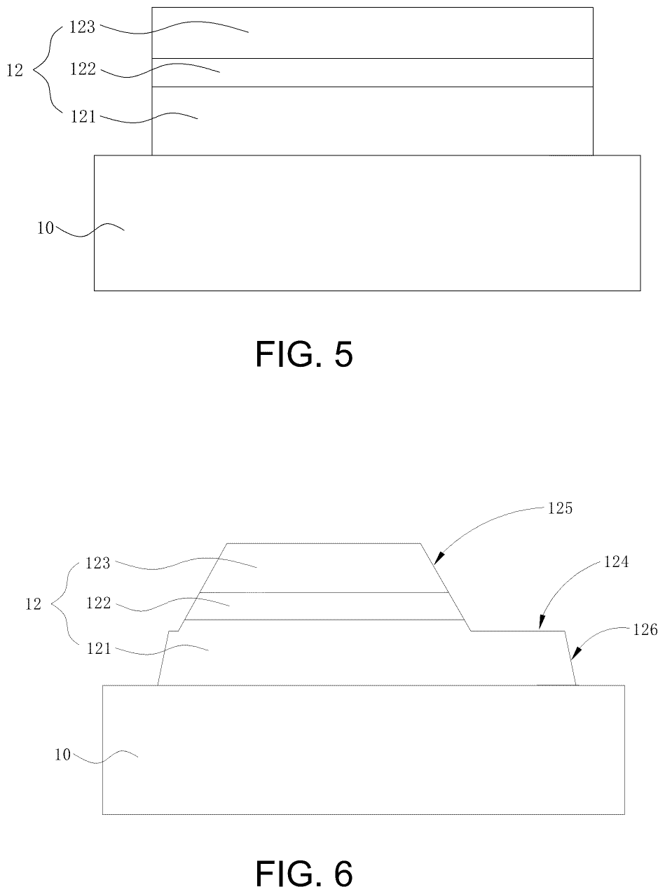

According to some embodiments of the disclosure, in the current red LED manufacturing process, a bevel process forms a right angle by a negative photoresist process in combination an inductively coupled plasma (ICP) dry etching process, and then forms a bevel by a hydrogen bromide (HBr) wet etching, thereby forming the first inclined sidewall 125. However, in this process, due to the anisotropic characteristics of wet etching, the degree of inclination of the first inclined sidewall 125 may not be precisely controlled, and thus the interval L1 between the first electrode 14 and the light emitting layer 122 may not be controlled within a predetermined range, which ultimately leads to poor reliability and poor ESD protection performance of the LED. Further, the process disposes a chemical vapor deposition (CVD) sacrificial layer on a surface of the semiconductor stack 12 before forming the terrace 124. The purpose of disposing the CVD sacrificial layer is to ensure that the semiconductor stack 12 is not be etched by HBr. However, A soaking process using the buffered oxide etch (BOE) is necessary to remove the CVD sacrificial layer. The soaking process using the BOE would cause the first inclined sidewall 125 of the semiconductor stack 12 to be side-etched, and hence form inwardly concave grooves thereon (as shown in FIG. 3, there is an obvious inwardly concave groove in the box area), thereby affecting the quality and performance of the LED.

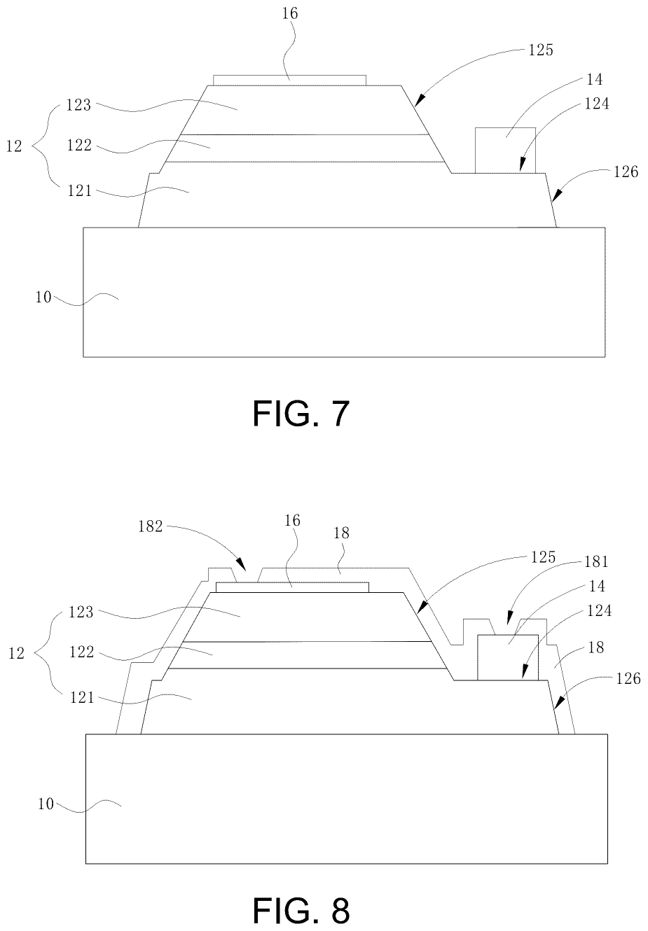

In order to solve the above problems, the disclosure adopts a positive photoresist process in combination with the ICP dry etching process to form the terrace 124 and the first inclined sidewall 125. The manufacturing method is that when the positive photoresist is exposed to ultraviolet light, the photosensitive part undergoes the photodecomposition reaction and is then soluble in the developer, while the unexposed part remains on the surface of the semiconductor stack 12, protecting the semiconductor stack 12 below from being etched. In the conventional negative photoresist process, the properties of the negative photoresist process are opposite to those of the positive photoresist process. Subsequently, the carrier plate used in the ICP etching process may be a metal carrier plate, which utilizes the heat dissipation characteristic of metal to deal with the carbonization issue of the positive photoresist due to heat. In addition, multiple through holes may be formed on the metal carrier plate, and the through holes are used to pass He gas for cooling, thereby further improving the problem of carbonization of the positive photoresist due to heat. In addition, the first inclined sidewall 125 formed by the positive photoresist process and the ICP dry etching process only requires one step to be formed, while the current red light LED preparation process still requires at least two steps when forming the first inclined sidewall 125, which is more difficult, complicated, and costly. The first inclined sidewall 125 formed by the positive photoresist process and the ICP dry etching process is shown in FIG. 4, and is a straight and flat inclined sidewall without concave defect.

The semiconductor stack 12 further has a second inclined sidewall 126, the upper and lower ends of which are respectively connected to the terrace 124 and a lower surface of the first semiconductor layer 121. An included angle C between the second inclined side wall 126 and the terrace 124 is in a range of 95° to 105°. In some embodiments, the LED is the red LED, and the terrace 124 is deeper relative to the upper surface of the second semiconductor layer 123 in comparison to the conventional LED. In this embodiment, a vertical distance H1 from the upper surface of the second semiconductor layer 123 to the terrace 124 is greater than 10 μm. In the conventional LED, the corresponding depth is about 1 to 3 μm.

The first electrode 14 is disposed on the terrace 124 and is electrically connected to the first semiconductor layer 121. The first electrode 14 may be a single-layer structure, a double-layer structure, or a multi-layer structure, such as Ti/Al, Ti/Al/Ti/Au, Ti/Al/Ni/Au, V/Al/Pt/Au, Au/Ge/Ni, and so on.

The second electrode 16 is electrically connected to the second semiconductor layer 123. The second electrode 16 may be made of a transparent conductive material or a metal material, which is decided according to the doping condition of the surface layer of the second semiconductor layer 123. In some embodiments, the second electrode 16 is made of the transparent conductive material, and the material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiments of the disclosure are not limited thereto.

By controlling the included angle B between the first inclined sidewall 125 and the terrace 124 to be in the range of 110° to 135° and controlling an interval L2 between the second electrode 16 and the first inclined sidewall 125 to be in a range of 3 μm or above, the current spreading effect can be improved and the light emitting performance of the LED can be improved. If the included angle is greater than 135°, the first inclined sidewall 125 is inclined toward the light emitting layer 122, which results in a smaller area of the light emitting layer 122. Further, an area on the upper surface of the second semiconductor layer 123 becomes smaller, thereby compressing the disposing space of the second electrode 16 located on the second semiconductor layer 123 and resulting in that the subsequently disposed second electrode 16 is unable to expand the current fully. If the included angle is less than 110°, the first inclined sidewall 125 is more vertical and steep. When the insulating layer 18 and the first pad 21 subsequently cover the terrace 124 and the first inclined sidewall 125, cracks and grooves would be easily formed, which affects the reliability of the LED.

The LED further includes a substrate 10, an insulating layer 18, a first pad 21, and a second pad 22. The semiconductor stack 12 is disposed on the substrate 10. The substrate 10 may be an insulating substrate 10, and may be made of a transparent material or a semi-transparent material. In some embodiments, the substrate 10 may be a sapphire substrate 10, but the disclosure is not limited thereto. The substrate 10 may also be made of a conductive material or a semiconductor material. For example, the material of the substrate 10 may include at least one of silicon carbide, silicon, magnesium aluminum oxide, magnesium oxide, lithium aluminum oxide, aluminum gallium oxide, and gallium nitride.

The insulating layer 18 covers the semiconductor stack 12, the first electrode 14, and the second electrode 16, and has a first opening 181 and a second opening 182. Different parts of the insulating layer 18 have different functions. For example, covering the side wall of the semiconductor stack 12 with the insulating layer 18 may prevent the first semiconductor layer 121 and the second semiconductor layer 123 from being electrically connected due to leakage of the conductive material, thereby avoiding short-circuit issue of the LED, but the embodiments of the disclosure are not limited to thereto. The material of the insulating layer 18 may include a non-conductive material. The non-conductive material is preferably to be inorganic material or dielectric material. The inorganic material may include silica gel. The dielectric material may include an electrically insulating material such as aluminum oxide, silicon nitride, silicon oxide, titanium oxide, or magnesium fluoride. For example, the insulating layer 18 may be silicon dioxide, silicon nitride, titanium oxide, tantalum oxide, niobium oxide, barium titanate, or a combination thereof. The combination thereof may be, for example, a distributed Bragg reflector (DBR) formed by two materials with different refractive indices stacked repeatedly.

The first pad 21 is disposed on the insulating layer 18 and is connected to the first electrode 14 via the first opening 181. The second pad 22 is disposed on the insulating layer 18 and is connected to the second electrode 16 via the second opening 182. The first pad 21 and the second pad 22 may be metal pads and may be formed together by the same material in the same process, and thus may have the same layer structure.

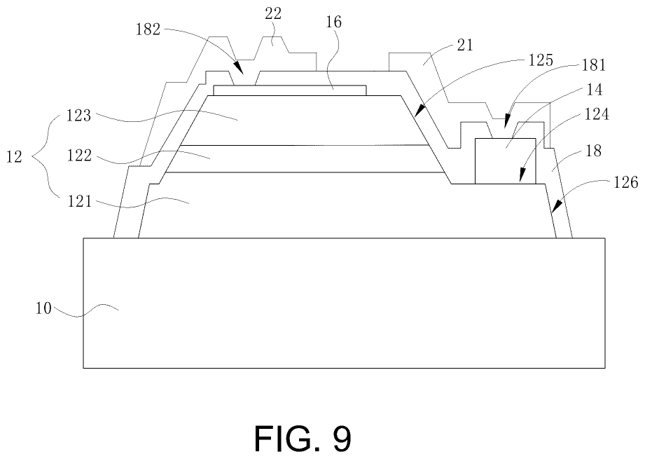

A manufacturing method of the LED shown in FIG. 1 is disclosed below. Please refer to FIG. 5 to FIG. 9, which are schematic views of the structure of the LED shown in FIG. 1 at various stages in a manufacturing process.

First, as shown in FIG. 5, the semiconductor stack 12 is disposed on the substrate 10. Afterwards, the positive photoresist is coated on the semiconductor stack 12, and the semiconductor stack 12 with a positive trapezoidal morphology is formed by exposure. In combination with the ICP dry etching process, a structure as shown in FIG. 6 is formed, that is, the terrace 124 and the first inclined sidewall 125 of the semiconductor stack 12 are formed.

Next, as shown in FIG. 7, the first electrode 14 and the second electrode 16 are disposed on the semiconductor stack 12. The first electrode 14 is disposed on the terrace 124 to be electrically connected to the first semiconductor layer 121. The second electrode 16 is disposed on the second semiconductor layer 123.

Afterwards, as shown in FIG. 8, the insulating layer 18 covers the semiconductor stack 12, the first electrode 14, and the second electrode 16, and is etched to form the first opening 181 and the second opening 182. The process of etching the insulating layer 18 may adopt the ICP dry etching process (the conventional method is wet etching). Since the insulating layer 18 under the flipped structure is relatively thick, the precision requirement for the tilt angle is relatively high. However, the tilt angle formed by wet etching is not stable enough, and when the insulating layer 18 includes at least two materials, the etching rates of different materials are inconsistent, which further cause the sidewall to be uneven. In addition, if the oxide layer is too thick, it is impossible to confirm whether the insulating layer 18 has been completely etched, and over-etching is required, which result in instability in the size and sidewall angle of the etched hole. The disclosure adopts the ICP dry etching process, which may ensure the stability of the tilt angle while presetting the thickness of the thin layer of metal on the surface of the lower electrode and confirming whether the ICP dry etching has been completely etched based on the characteristic that the metal presents different colors at different thicknesses.

Finally, as shown in FIG. 9, the first pad 21 and the second pad 22 are disposed on the insulating layer 18. The first pad 21 is connected to the first electrode 14 via the first opening 181. The second pad 22 is connected to the second electrode 16 via the second opening 182.

The above is only the disclosed manufacturing method of the LED shown in FIG. 1, which is not limited by the disclosure, but is only used to illustrate the manufacturing method of the LED.

The disclosure further provides a light emitting device, which adopts the LED provided by any of the above embodiments.

Table 1 below shows comparative data on the ESD protection performance between the conventional LED and the LED of the disclosure. As can be seen from the data, the LED of the disclosure can ensure a pass rate (yield) of at least 90%, and has a significant improvement in yield compared to the conventional LED no matter when a breakdown voltage of 1500V, 2000V, or 3000V is applied.

TABLE 1

| | Conventional LED | LED of the disclosure |
|---|---|---|
| Pass rate of ESD1500 V | 96.70% | 99.45% |
| Pass rate of ESD2000 V | 90% | 97% |
| Pass rate of ESD3000 V | 46% | 92% |

An embodiment of the disclosure provides the LED and the light emitting device. By controlling the included angle B between the first inclined sidewall 125 and the terrace 124 to be in the range of 110° to 135° and controlling the interval L1 between the first electrode 14 and the light emitting layer 122 to be in the range of 4 μm to 13 μm, the reliability and the ESD protection performance of the LED can be improved.

In addition, people skilled in the art should understand that, although there are many problems in the related art, each embodiment or technical solution of the disclosure may be improved in only one or several aspects without having to solve all technical problems listed in the related art or background technology at the same time. It should be understood by people skilled in the art that any content not mentioned in a claim should not be regarded as limiting the claim.

Finally, it should be noted that the above embodiments are only used to illustrate the technical solutions of the disclosure, rather than to limit them. Although the disclosure has been described in detail with reference to the foregoing embodiments, people skilled in the art should understand that the technical solutions described in the foregoing embodiments may still be modified, or some or all of the technical features thereof may be replaced by equivalents. However, these modifications or substitutions do not make the essence of the corresponding technical solutions deviate from the scope of the technical solutions of the embodiments of the disclosure.

What is claimed is:

1. A light emitting diode, comprising:
a semiconductor stack, wherein the semiconductor stack comprises a first semiconductor layer, a light emitting layer, and a second semiconductor layer stacked in sequence, the semiconductor stack has a terrace, and the terrace is an upper surface of the first semiconductor layer which is not covered by the light emitting layer;
a first electrode, located on the terrace and electrically connected to the first semiconductor layer;
a second electrode, electrically connected to the second semiconductor layer;
wherein the semiconductor stack has a first inclined sidewall, two ends of the first inclined sidewall are respectively connected to an upper surface of the second semiconductor layer and the terrace, an included angle between the first inclined sidewall and the terrace is in a range of 110° to 135°, and an interval between the first electrode and the light emitting layer is in a range of 2.5 μm to 13 μm.

2. The light emitting diode according to claim 1, wherein the semiconductor stack further has a second inclined side wall, two ends of the second inclined side wall are respectively connected to a lower surface of the first semiconductor layer and the terrace, and an included angle between the second inclined side wall and the terrace is in a range of 95° to 105°.

3. The light emitting diode according to claim 1, wherein an interval between the second electrode and the first inclined sidewall is greater than or equal to 3 μm.

4. The light emitting diode according to claim 1, wherein the light emitting diode further comprises a substrate, an insulating layer, a first pad, and a second pad, the semiconductor stack is disposed on the substrate, the insulating layer covers the semiconductor stack, the first electrode, and the second electrode, the insulating layer has a first opening and a second opening, the first pad is disposed on the insulating layer, the first pad is connected to the first electrode via the first opening, the second pad is disposed on the insulating layer, and the second pad is connected to the second electrode via the second opening.

5. The light emitting diode according to claim 1, wherein a vertical distance between the upper surface of the second semiconductor layer and the terrace is greater than 10 μm.

6. The light emitting diode according to claim 1, wherein the first inclined sidewall is formed by a positive photoresist process in combination with an inductively coupled plasma (ICP) etching process.

7. The light emitting diode according to claim 6, wherein a carrier plate used in the ICP etching process is a metal carrier plate, and a plurality of through holes are formed on the metal carrier plate.

8. The light emitting diode according to claim 1, wherein the first inclined sidewall is formed by one step of a preparation process.

9. The light emitting diode according to claim 1, wherein the first semiconductor layer is an N-type semiconductor layer, and the second semiconductor layer is a P-type semiconductor layer.

10. The light emitting diode according to claim 1, wherein the light emitting diode is a flipped structure.

11. The light emitting diode according to claim 1, wherein the light emitting diode is a red light emitting diode.

12. A light emitting device, comprising the light emitting diode according to claim 1.
